(19) United States
(12) Patent Application Publication
(10) Pub. No.: US 2019/0103492 A1
(43) Pub. Date: Apr. 4, 2019

(54) METHOD FOR FABRICATING SEMICONDUCTOR DEVICE INVOLVING FORMING EPITAXIAL MATERIAL

(71) Applicant: United Microelectronics Corp., Hsinchu (TW)

(72) Inventors: Cheng-Pu Chiu, New Taipei City (TW); Pei-Yu Chen, Nantou County (TW); Shih-Min Lu, Tainan City (TW); Ming-Yueh Tsai, Taichung City (TW); Yung-Sung Lin, Tainan City (TW); Te-Chang Hsu, Tainan City (TW); Chih-Yi Wang, Tainan City (TW); Chi-Hsuan Cheng, Kaohsiung City (TW); Sheng-Chen Chung, Tainan City (TW); Yao-Jhan Wang, Tainan City (TW)

(73) Assignee: United Microelectronics Corp., Hsinchu (TW)

(21) Appl. No.: 15/722,801

(22) Filed: Oct. 2, 2017

(51) Int. Cl. H01L 29/78; H01L 29/08; H01L 29/161; H01L 29/165; H01L 29/20; H01L 29/267; H01L 29/66; H01L 21/02

(52) U.S. Cl. CPC H01L 29/7847; H01L 29/0847; H01L 29/161; H01L 29/165; H01L 29/20; H01L 29/7851; H01L 29/66575; H01L 21/0217; H01L 21/02532; H01L 21/02546; H01L 29/267

(57) ABSTRACT

A method for forming epitaxial material on base material includes forming a stress cap layer on a base layer of a first semiconductor material. Then, a stress is induced on the base layer, wherein the stress is a tensile stress or a compressive stress. The stress cap layer is removed. An epitaxial layer of a second semiconductor material is formed on the base layer, wherein the second semiconductor material is different from the first semiconductor material.

### BACKGROUND

### 1. Field of the Invention

The present invention generally relates to semiconductor fabrication, and particularly to method for fabricating a semiconductor device, involving forming epitaxial material.

### 2. Description of Related Art

Various electronic products, such as computer, digital camera, cellular phone, tablet computer, memory device, driver, and so on, have been commonly known and used in daily life. The electronic apparatus includes an integrated circuit, which includes a large number of field effect transistors fabricated by semiconductor fabrication technology. The performance and size of the electronic products are very dependent on the design of the transistors.

As the semiconductor fabrication technology is greatly and continuously developed, the semiconductor device is no longer just based on silicon as the base. Taking the transistor design as the example, the source region and the drain region is not limited to the doped silicon. Instead, the source region and the drain region may be formed based on other suitable semiconductor materials, such as III-V material or SiGe or any suitable material. In other word, the semiconductor device may include epitaxial semiconductor material other than silicon. The epitaxial layer in an example is formed by growth on the silicon material.

The quality of the epitaxial layer would affect the performance for the semiconductor device, or metal-oxide-semiconductor (MOS) device, or the field effect transistor. It is at least an issue to improve the epitaxial growth quality of a semiconductor layer on the semiconductor base in different material.

### SUMMARY OF THE INVENTION

The invention provides a method for fabricating a semiconductor device, involving the growth of epitaxial material on a base material. The invention uses the stress memorization technique (SMT) to adjust the lattice constant of the epitaxial layer to approach to the lattice constant of the base material. The growth quality of the epitaxial layer can be improved, so the epitaxial layer can have better quality.

In an embodiment, the invention provides a method for forming epitaxial material on base material including forming a stress cap layer on a base layer of a first semiconductor material. Then, a stress is induced on the base layer, wherein the stress is a tensile stress or a compressive stress. The stress cap layer is removed. An epitaxial layer of a second semiconductor material is formed on the base layer, wherein the second semiconductor material is different from the first semiconductor material.

In an embodiment, as to the method for forming epitaxial material, the stress changes a first lattice constant at an interface of the base layer to approach to a second lattice constant of the epitaxial layer.

In an embodiment, as to the method for forming epitaxial material, the stress cap layer is a stress memorization technique (SMT) layer.

In an embodiment, as to the method for forming epitaxial material, the step of inducing the stress on the base layer comprises applying an operation temperature on the SMT layer.

In an embodiment, as to the method for forming epitaxial material, the stress cap layer is a silicon nitride film, wherein the silicon nitride film is a tensile nitride film or a compressive nitride film.

In an embodiment, as to the method for forming epitaxial material, the step of inducing the stress on the base layer comprises applying an operation temperature on the silicon nitride film.

In an embodiment, as to the method for forming epitaxial material, the first semiconductor material is silicon and the second semiconductor material is III-V material, SiGe, GaAs, InGaAs, or a predetermined material, wherein the first semiconductor material is III-V material, SiGe, GaAs, InGaAs, or a predetermined material and the second semiconductor material is silicon.

In an embodiment, the invention provides a method for fabricating a semiconductor device, including providing a substrate, having an exposed surface of a first semiconductor material on the substrate. Then, a stress cap layer is formed on the first semiconductor surface. A stress is induced on the exposed surface, wherein the stress is a tensile stress or a compressive stress. The stress cap layer is removed. An epitaxial material of a second semiconductor material is grown on the exposed surface, wherein the second semiconductor material is different from the first semiconductor material.

In an embodiment, as to the method for fabricating a semiconductor device, the stress changes a first lattice constant at the exposed surface to approach to a second lattice constant of the epitaxial material.

In an embodiment, as to the method for fabricating a semiconductor device, the exposed surface is from an indent of a semiconductor substrate, and the epitaxial material is grown in the indent.

In an embodiment, as to the method for fabricating a semiconductor device, the exposed surface is from an indent of a semiconductor substrate, and the epitaxial material is grown in the indent to serve as a source region or a drain region of a field effect transistor (FET).

In an embodiment, as to the method for fabricating a semiconductor device, the field effect transistor is a metal-oxide-semiconductor (MOS) FET or a fin FET.

In an embodiment, as to the method for fabricating a semiconductor device, the stress cap layer is a stress memorization technique (SMT) layer.

In an embodiment, as to the method for fabricating a semiconductor device, the step of inducing the stress on the base layer comprises applying an operation temperature on the SMT layer.

In an embodiment, as to the method for fabricating a semiconductor device, the stress cap layer is a silicon nitride film, wherein the silicon nitride film is a tensile nitride film or a compressive nitride film.

In an embodiment, as to the method for fabricating a semiconductor device, the step of inducing the stress on the base layer comprises applying an operation temperature on the silicon nitride film.

In an embodiment, as to the method for fabricating a semiconductor device, the first semiconductor material is silicon and the second semiconductor material is III-V material, SiGe, GaAs, InGaAs, or a predetermined material, wherein the first semiconductor material is III-V material, SiGe, GaAs, InGaAs, or a predetermined material and the second semiconductor material is silicon.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1C are cross-sectional drawings, schematically illustrating a method for forming an epitaxial material on a base material, according to an embodiment of the invention.

FIG. 2A to FIG. 2C are cross-sectional drawings, schematically illustrating a method for forming an epitaxial material on a base material, according to an embodiment of the invention.

FIG. 3A to FIG. 3B are cross-sectional drawings, schematically illustrating a method for forming an epitaxial material on a base material, according to an embodiment of the invention.

FIG. 4 is a drawing, schematically illustrating an application to a fin field effect transistor (FinFET), according to an embodiment of the invention.

FIG. 5 is a drawing, schematically illustrating a top view of a part of FinFET, according to an embodiment of the invention.

FIG. 6 is a drawing, schematically illustrating a cross-sectional view of a part of FinFET, according to an embodiment of the invention.

### DESCRIPTION OF THE EMBODIMENTS

The invention is directed to method for fabricating a semiconductor device, involving forming an epitaxial material on a base material. A SMT layer is used to adjust the lattice constant of the base material. As a result, the lattice constant of base material can be changed to approach to the lattice constant of epitaxial material. Since the lattice constants are matched in better condition, the epitaxial growth quality can be significantly improved. The epitaxial layer is grown well on the base material.

Several embodiments are provided for describing the invention. However, the invention is not limited to the embodiments as provided.

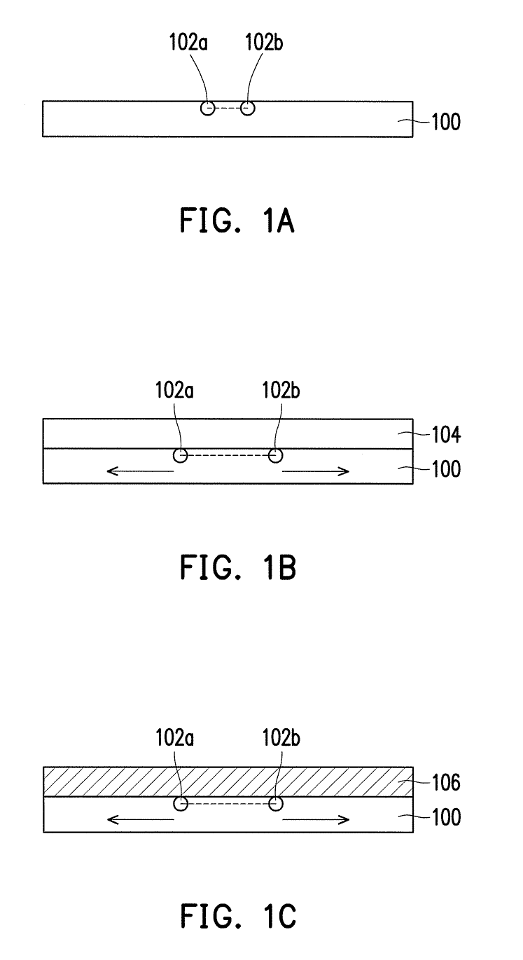

FIG. 1A to FIG. 1C are cross-sectional drawings, schematically illustrating a method for forming an epitaxial material on a base material, according to an embodiment of the invention.

Referring to FIG. 1A, a base layer 100 is provided. Here, the base layer 100 can be a silicon layer or other semiconductor layer without limiting to. However, taking the silicon layer as the base layer, in an embodiment, the silicon layer can also be a silicon substrate. The base layer 100 may be an exposed layer of the semi-completion semiconductor structure. In other word, the base layer 100 represents a portion of the layer to be grown with epitaxial layer later. The adjacent two lattice points 102a, 102b of the base layer 100 has a lattice constant.

The material of the epitaxial layer to be forming on the base layer can be the semiconductor material other than silicon, such as the III-V material, or SiGe, GaAs, InGaAs, or any suitable material. The lattice constant of the epitaxial layer usually is larger than the lattice constant of the silicon material from the silicon substrate. If an epitaxial layer 106 in FIG. 1C is to be formed on the base layer 100. The difference of lattice constants between the epitaxial layer 106 and the base layer would cause the difficulty to form the epitaxial layer 106 in well condition.

The invention has involved a SMT layer to adjust the lattice constant of the base layer 100. Referring to FIG. 1B, a SMT layer 104 is formed on the base layer 100. The SMT layer 104 is formed of single layer or multi-layer of silicon nitride (SixNy), silicon oxynitride (SiON), silicon carbide (SiC), silicon carbon nitride (SiCN), or a combination thereof. The SMT layer 104 may be formed in accordance with any prior art (or later developed) processes or techniques, including plasma enhanced chemical vapor deposition (PECVD), atomic layer deposition (ALD), physical vapor deposition (PVD), spin-on dielectric (SOD) process, and the like. The SMT layer 104 may have a thickness in the range of about 250 to about 1500 Angstroms. In an example, the thickness may be increased above 1000 Angstroms in order to increase the memorization stress induced. As is known, the deposition parameters (e.g., pressure, temperature, bias voltage and the like) during the PECVD process for depositing the silicon nitride may be selected to provide the desire stress (tensile or compressive, and magnitude). In an example, the stress of SMT layer 104 on the base layer 100 is induced by a thermal control. The thermal control can be thermal curing, ultra-violet (UV) curing, electron beam curing or laser curing. The wafer (structure) is cured at a temperature ranging between 200 and 500 degrees C. for between 1 to 60 minutes. The SMT layer 104 can also be generally referred as a stress cap layer to cap over an intended portion of a base structure. The material of the SMT layer 104 in the embodiment is a tensile nitride film which produce a tensile effect to respond an applied temperature, in an example. Here, the tensile effect is provided in an example. As a result, the SMT layer 104 produces the tensile stress on the base layer 100, so to increase the lattice constant between adjacent two lattice points. Base on the physical property of the SMT, the tensile stress causes the lattice constant of the base layer 100 to approach to or equal to the lattice constant of the epitaxial layer 106 before the epitaxial layer 106 is formed on the base layer 100.

Referring to FIG. 1C, after the SMT layer 104 with the intended tensile stress changes the lattice constant of the base layer 100, the SMT layer 104 is removed. Then, the epitaxial layer 106 is formed on the base layer. Since the lattice constant of the base layer has been expanded to approach to the epitaxial layer 106, the epitaxial layer 106 can be easier to grow with better quality. The epitaxial layer 106 can provide the structure row base to be further processed later to form the structure, according to design. The application of the epitaxial layer 106 is not limited to forming the source region and the drain region. The epitaxial layer 106 can also serve as a layer for forming a doped well, in an example.

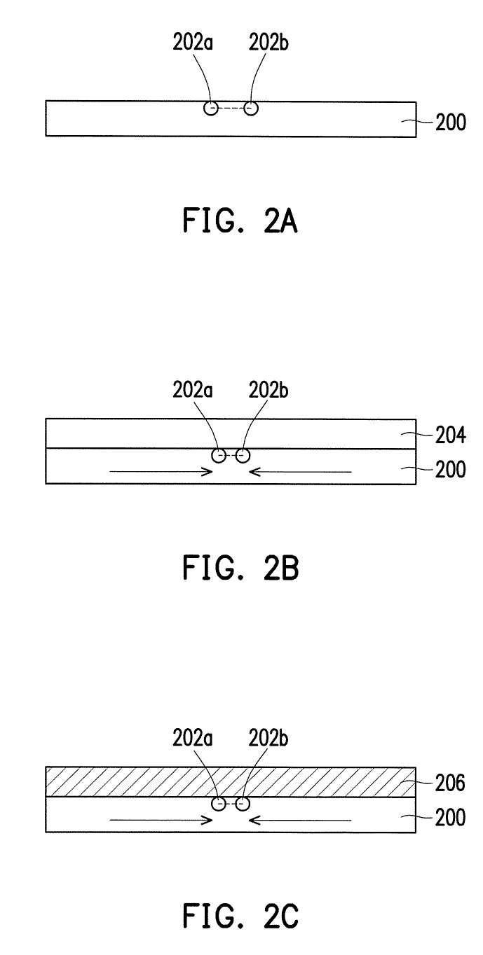

The stress produced by the SMT layer 104 can be a compressive stress in another embodiment. FIG. 2A to FIG. 2C are cross-sectional drawings, schematically illustrating a method for forming an epitaxial material on a base material, according to an embodiment of the invention.

Referring to FIG. 2A, the base layer 200 is provided. The base layer 200 in the example has a larger lattice constant, which is to be compressed to approach to the epitaxial layer 204 in FIG. 2C. In an example, the material of the base layer 200 can be III-V material, SiGe, GaAs or InGaAs while the epitaxial layer is silicon. However, the invention is not limited to the embodiment.

Referring to FIG. 2B, the SMT layer 204 in the example, such as the compressive nitride film, is to produce the compressive stress. As a result, the lattice constant, that is, the distance between the two lattice points 202a and 202b is compressed.

Referring to FIG. 2C, after removing the SMT layer 204, the epitaxial layer 206 with smaller lattice constant than that of the base layer 200 is formed on the base layer 200. Since the lattice constant of the base layer 200 has been adjusted by the control of the SMT layer 204, the lattice constants between the base layer and the epitaxial layer can approach to or equal to the same. This allows the epitaxial layer 206 to be easily grown with better condition.

As to the above embodiments, it can be seen that the tensile stress or the compressive stress is induced depending on the lattice constant of the epitaxial layer to be formed on the base layer. In examples, the semiconductor material of the base layer can be silicon and then the semiconductor material of the base layer can be III-V material, SiGe, GaAs or InGaAs, or a suitable material as predetermined. Alternatively, if the semiconductor material of the epitaxial layer can be III-V material, SiGe, GaAs, InGaAs, or a suitable material as predetermined and then the semiconductor material of the base layer can be silicon. Generally, the lattice constants for the epitaxial layer and the base layer are different, and the SMT layer producing the tensile or compressive stress is used to adjust the lattice constant of the base layer.

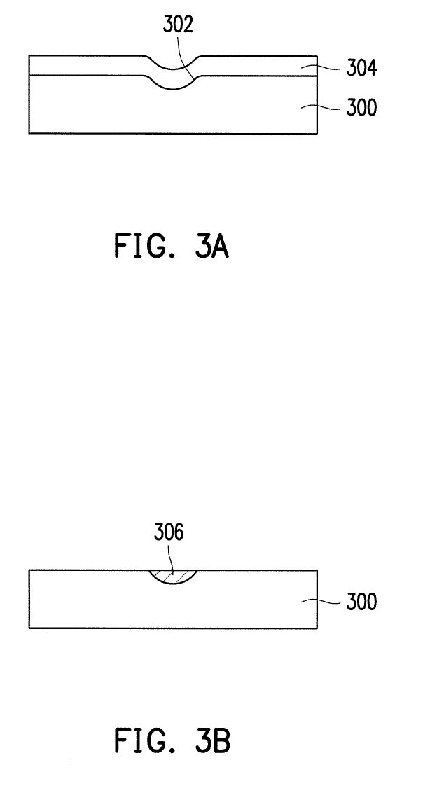

FIG. 3A to FIG. 3B are cross-sectional drawings, schematically illustrating a method for forming an epitaxial material on a base material, according to an embodiment of the invention.

Referring to FIG. 3A, as the development to form the source region and the drain region for the FET in an example, the SiGe material can be formed in a concave region of the silicon substrate to serve as the source region and the drain region. The substrate 300 is patterned to have a concave region 302, where the source/drain region is to be formed later in an example. Then, the SMT layer 304 is formed on the substrate layer 300. The tensile effect or the compressive effect as described in FIG. 1A to FIG. 1C and FIG. 2A to FIG. 2C can be produced to adjust the lattice constant.

Referring to FIG. 3B, in the example, after the SMT layer 304 is removed, the epitaxial layer 306, such as the SiGe, is formed in the concave region 302. The epitaxial layer 306 can serve as the base for forming the source region and the drains region of the FET, in an example. However, the invention is not just limited to.

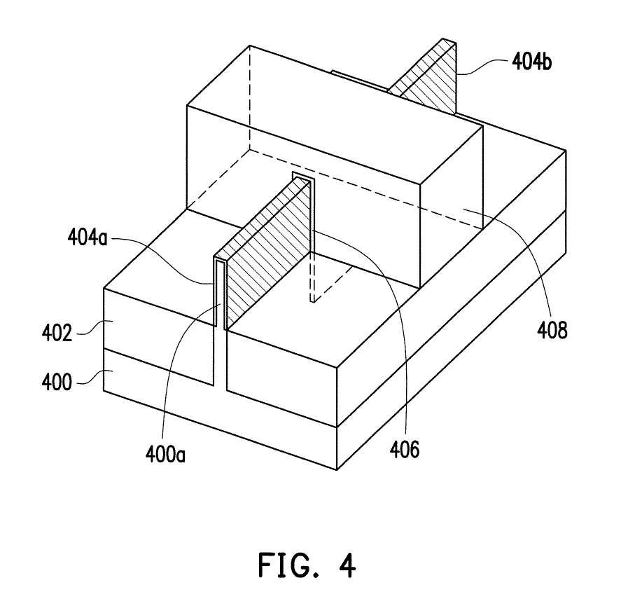

The invention can also be applied to the FinFET. FIG. 4 is a drawing, schematically illustrating an application to a fin field effect transistor (FinFET), according to an embodiment of the invention.

Referring to FIG. 4, as the development of FET, the FinFET structure has been proposed, in which the source region 404a and the drain region 404b are formed on the fin structure 400a of the substrate 400. The source region 404a and the drain region 404b can be formed from the semiconductor material other than silicon.

In FinFET structure, the substrate 400, such as the silicon substrate, is patterned to form the fin structure 400a, which is protruding out from the substrate 400. An inter-dielectric layer 402 is disposed on the substrate 400 and also covers a base part of the fin structure 400. A gate oxide layer 406 is formed on the fin structure 400a, further the gate layer 408 is formed on the inter-dielectric layer 402 and crosses over fin structure 400a on the gate oxide layer 406. The surface of the fin structure 400a at both sides of the gate layer 408 are the source region 404a and the drain region 404b.

Conventionally, the source region 404a and the drain region 404b are directly formed on the surface of the silicon fin structure 400a by directly implanting dopants into the silicon. However, in the invention, the source region 404a and the drain region 404b can be formed by SiGe in an embodiment to grow from the fin structure 400a.

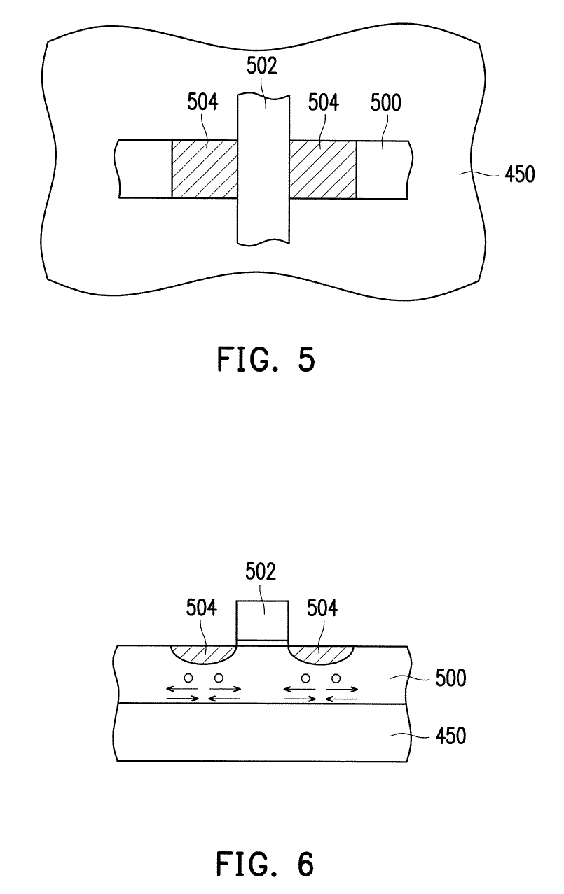

In a further embodiment for the FinFET structure, the structure in FIG. 3B may be applied in combination. FIG. 5 is a drawing, schematically illustrating a top view of a part of FinFET, according to an embodiment of the invention. FIG. 6 is a drawing, schematically illustrating a cross-sectional view of a part of FinFET, according to an embodiment of the invention.

Referring to FIG. 5 and FIG. 6, taking the FinFET based on the silicon substrate as an example, the substrate 450 has been patterned to have the fin structure 500, which is a protruding portion. The gate layer 502 is crossing over the fin structure 500. In this example, the source/drain regions 504 can be formed from the SiGe material according to the method as shown in FIG. 3B. The SiGe material is formed in the source/drain regions 504. Before the source/drain regions 504 of SiGe is formed, the lattice constant of the fin structure 500 is adjusted by the SMT process to have a proper lattice constant, so to approach to the lattice constant of the SiGe material to be grown.

However, the structures in the embodiments are just for showing the application of the invention. The invention is not just limited to the applications of the provided embodiments. The lattice points as indicated by arrows depending on the material properties would be tensile or compressive.

The SMT layer in the invention is applied to adjust the lattice constant of the base layer before the epitaxial layer is grown from the base layer.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for forming epitaxial material on base material, comprising:
forming a stress cap layer on a base layer of a first semiconductor material;
inducing a stress on the base layer, wherein the stress is a tensile stress or a compressive stress;
removing the stress cap layer; and
forming an epitaxial layer of a second semiconductor material on the base layer, wherein the second semiconductor material is different from the first semiconductor material.

2. The method of claim 1, wherein the stress changes a first lattice constant at an interface of the base layer to approach to a second lattice constant of the epitaxial layer.

3. The method of claim 1, wherein the stress cap layer is a stress memorization technique (SMT) layer.

4. The method of claim 3, wherein the step of inducing the stress on the base layer comprises applying an operation temperature on the SMT layer.

5. The method of claim 1, wherein the stress cap layer is a silicon nitride film, wherein the silicon nitride film is a tensile nitride film or a compressive nitride film.

6. The method of claim 5, wherein the step of inducing the stress on the base layer comprises applying an operation temperature on the silicon nitride film.

7. The method of claim 1, wherein the first semiconductor material is silicon and the second semiconductor material is III-V material, SiGe, GaAs or InGaAs or a predetermined material, wherein the first semiconductor material is III-V material, SiGe, GaAs, InGaAs or a predetermined material and the second semiconductor material is silicon.

8. A method for fabricating a semiconductor device, comprising:
providing a substrate, having an exposed surface of a first semiconductor material on the substrate;
forming a stress cap layer on the first semiconductor surface;
inducing a stress on the exposed surface, wherein the stress is a tensile stress or a compressive stress;
removing the stress cap layer; and
growing an epitaxial material of a second semiconductor material on the exposed surface, wherein the second semiconductor material is different from the first semiconductor material.

9. The method of claim 8, wherein the stress changes a first lattice constant at the exposed surface to approach to a second lattice constant of the epitaxial material.

10. The method of claim 8, wherein the exposed surface is from an indent of a semiconductor substrate, and the epitaxial material is grown in the indent.

11. The method of claim 8, wherein the exposed surface is from an indent of a semiconductor substrate, and the epitaxial material is grown in the indent to serve as a source region or a drain region of a field effect transistor (FET).

12. The method of claim 8, wherein the field effect transistor is a metal-oxide-semiconductor (MOS) FET or a fin FET.

13. The method of claim 8, wherein the stress cap layer is a stress memorization technique (SMT) layer.

14. The method of claim 13, wherein the step of inducing the stress on the base layer comprises applying an operation temperature on the SMT layer.

15. The method of claim 8, wherein the stress cap layer is a silicon nitride film, wherein the silicon nitride film is a tensile nitride film or a compressive nitride film.

16. The method of claim 15, wherein the step of inducing the stress on the base layer comprises applying an operation temperature on the silicon nitride film.

17. The method of claim 8, wherein the first semiconductor material is silicon and the second semiconductor material is III-V material, SiGe, GaAs, InGaAs, or a predetermined material, wherein the first semiconductor material is III-V material, SiGe, GaAs, InGaAs or a predetermined material and the second semiconductor material is silicon.
